(19) United States
(12) Patent Application Publication
(10) Pub. No.: US 2012/0063987 A1
(43) Pub. Date: Mar. 15, 2012

(54) GROUP-III NITRIDE CRYSTAL AMMONOTHERMALLY GROWN USING AN INITIALLY OFF-ORIENTED NON-POLAR OR SEMI-POLAR GROWTH SURFACE OF A GROUP-III NITRIDE SEED CRYSTAL

(75) Inventors: Siddha Pimputkar, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/048,179

(22) Filed: Mar. 15, 2011

Related U.S. Application Data
(60) Provisional application No. 61/314,095, filed on Mar. 15, 2010.

(51) Int. Cl. C01B 21/06; C30B 7/10

(52) U.S. Cl. 423/409; 117/71; 117/224; 423/406

(57) ABSTRACT

A method for ammonothermally growing group-III nitride crystals using an initially off-oriented non-polar and/or semi-polar growth surface on a group-III nitride seed crystal. Group-III-containing source materials and group-III nitride seed crystals are placed into a vessel, wherein the seed crystals have one or more non-polar or semi-polar growth surfaces. Group-III nitride crystals are ammonothermally grown by filling the vessel with a nitrogen-containing solvent for dissolving the source materials and transporting a fluid comprised of the solvent with the dissolved source materials to the seed crystals for growth of the group-III nitride crystals on the seed crystals. The growth surfaces are initially off-oriented growth surfaces, wherein the growth surfaces are off-oriented m-plane or highly vicinal m-plane growth surfaces. The growth surfaces of the seed crystals may be created by cutting group-III nitride crystals at a desired angle with respect to an m-plane.

### CROSS REFERENCE TO RELATED APPLICATIONS

This application claims priority under 35 U.S.C. §119(e) to co-pending and commonly-assigned U.S. Provisional Patent Application Ser. No. 61/314,095, filed on Mar. 15, 2010, by Siddha Pimputkar, James S. Speck, and Shuji Nakamura, and entitled “GROUP-III NITRIDE CRYSTAL GROWN USING AN INITIALLY OFF-ORIENTED NON-POLAR AND/OR SEMI-POLAR GROUP-III NITRIDE AS A SEED CRYSTAL USING THE AMMONOTHERMAL METHOD AND METHOD OF PRODUCING THE SAME,” attorney's docket number 30794.376-US-P1 (2010-585-1), which application is incorporated by reference herein.

### BACKGROUND OF THE INVENTION

1. Field of the Invention

This invention relates to a method for ammonothermally growing group-III nitride crystals using an initially off-oriented non-polar and/or semi-polar growth surface of a group-III nitride seed crystal.

2. Description of the Related Art

The terms “group-III nitride” or “III-nitride” or “(Ga,Al,In,B)N” as used herein are intended to be broadly construed to include respective nitrides of the single species, Al, Ga, In and B, as well as binary, ternary and quaternary compositions of such Group III metal species. Accordingly, these include the compounds AN, GaN, and InN, as well as the ternary compounds AlGaN, GaInN, and AlInN, and the quaternary compound AlGaInN, as species included in such nomenclature. Accordingly, it will be appreciated that the discussion of the invention hereinafter in reference to GaN materials is applicable to the formation of various other (Ga,Al,In,B)N material species. Further, (Ga,Al,In,B)N materials within the scope of the invention may further include minor quantities of dopants and/or other impurity or inclusional materials.

Ammonothermal growth of group-III nitrides, for example, GaN, involves placing within a reaction vessel, such as an autoclave, group-III containing source materials, group-III nitride seed crystals, and a nitrogen-containing fluid or gas solvent, such as ammonia, sealing the vessel, and heating the vessel to conditions such that the vessel is at elevated temperatures (between 23° C. and 1000° C.) and high pressures (between 1 atm and, for example, 30,000 atm). Under these temperatures and pressures, the nitrogen-containing solvent becomes a supercritical fluid and normally exhibits enhanced solubility of group-III nitride material into solution. The solubility of group-III nitride into the nitrogen-containing fluid is dependent on the temperature, pressure and density of the fluid, among other things. By creating two different zones within the vessel, it is possible to establish a solubility gradient, where in one zone the solubility will be higher than in a second zone. The source material is then preferentially placed in the higher solubility zone and the seed crystals in the lower solubility zone. By establishing fluid motion between these two zones, for example, by making use of natural convection, it is possible to transport group-III nitride material from the higher solubility zone to the lower solubility zone where it then deposits itself onto the seed crystals.

Ammonothermal growth of group-III nitrides currently results in fast growth rates along a polar c-plane {0001} direction and slower growth along other directions. (Note that braces, { }, denote a family of symmetry-equivalent planes, where all planes within a single crystallographic family are equivalent for the purposes of this invention.) However, conventional, c-plane oriented, group-III nitride based optoelectronic and electronic devices exhibit strong piezoelectric and spontaneous polarization effects along this c-axis.

One approach to decreasing polarization effects in group-III nitride devices is to grow the devices on non-polar planes of the crystal. The term “non-polar plane” includes the {11-20} planes, known collectively as a-planes, and the {10-10} planes, known collectively as m-planes, which are orthogonal to the polar c-plane {0001} that is typically used for group-III nitride devices. Non-polar planes contain equal numbers of gallium and nitrogen atoms per plane and are charge-neutral.

Another approach to reducing polarization effects in group-III nitride devices is to grow the devices on semi-polar planes of the crystal. The term “semi-polar plane” can be used to refer to any plane that cannot be classified as c-plane, a-plane, m-plane, or planes orthogonal to the c-plane {0001}. In crystallographic terms, a semi-polar plane would be any plane that has at least two nonzero h, i, or k Miller indices and a nonzero 1 Miller index. Subsequent semi-polar layers are equivalent to one another, so the bulk crystal will have reduced polarization along the growth direction.

Currently, when growing group-III nitride crystals using the ammonothermal method, it may be possible that the growth along one crystallographic direction is slower than along another one. What may be seen (when growing, for example, GaN) is that the growth rate along the polar c-plane {0001} direction is approximately four to ten times faster than along a perpendicular, stable non-polar direction, such as the m-direction <10-10>. Additionally, the absolute growth rate along the stable, non-polar direction may be relatively small, on the order of 10-50 μm/day. In order to fabricate substrates from bulk group-III nitride crystals, it is desirable to obtain the highest possible growth rates, while still maintaining crystal quality.

If one desires to produce substrates which have a large non-polar and/or semi-polar surface, it is desirable to have rapid growth rates along the c-direction, but also along a perpendicular non-polar direction. It has been observed that growth in the a-direction <11-20>, which can be both perpendicular to the m-direction and c-direction, can be up to 10 times faster, yet the quality of the material growth is typically inferior to the seed crystal itself. Additionally, the a-plane typically grows out of existence and multiple m-plane facets form, replacing the original a-plane surface of the seed.

Thus, there is a need in the art for improved methods of ammonothermal growth along non-polar and/or semi-polar growth surfaces of group-III nitride crystals. The present invention satisfies these needs.

### SUMMARY OF THE INVENTION

The present invention discloses a method and apparatus for ammonothermally growing group-III nitride crystals using initially off-oriented non-polar and/or semi-polar growth surfaces of group-III nitride seed crystals. The present invention also discloses group-III nitride seed crystals for use in the method, and group-III nitride crystals grown by the method.

In the present invention, group-III-containing source materials and group-III nitride seed crystals are placed into a vessel, wherein the seed crystals have one or more non-polar or semi-polar growth surfaces. Group-III nitride crystals are then ammonothermally grown by filling the vessel with a nitrogen-containing solvent for dissolving the source materials and transporting a fluid comprised of the solvent with the dissolved source materials to the seed crystals for growth of the group-III nitride crystals on the seed crystals.

The non-polar or semi-polar growth surfaces of the seed crystals are initially off-oriented growth surfaces, wherein the initially off-oriented growth surfaces are off-oriented m-plane growth surfaces.

The off-oriented m-plane growth surfaces may be created by cutting group-III nitride crystals at a desired angle with respect to an m-plane of the group III nitride crystal, wherein the off-oriented m-plane growth surfaces have an off-orientation in an a-plane direction or a c-plane direction. The off-orientation in the a-plane direction may range from approximately 0° to approximately 15°. The off-orientation in the c-plane direction may range from approximately 0° to approximately 45°.

Moreover, the seed crystals may be coarsened along non-polar or semi-polar directions prior to the ammonothermal growth.

The ammonothermally grown group-III nitride crystals have an increased growth rate along a non-polar or semi-polar direction as compared to group-III nitride crystals not ammonothermally grown on non-polar or semi-polar seed crystals.

### BRIEF DESCRIPTION OF THE DRAWINGS

Referring now to the drawings in which like reference numbers represent corresponding parts throughout:

FIG. 1 plots the growth rate of m-plane GaN crystals as a function of off-orientation towards the a-plane.

FIG. 2 plots the crystal quality of m-plane GaN crystals as a function of off-orientation towards the a-plane.

FIG. 3 is a schematic illustrating the final group-III nitride crystal formed after a growth on the m-plane seed with finite off-orientation towards the a-plane.

FIG. 4 is a graph illustrating the effect of growing on m-plane seed crystals with a miscut towards the a-plane.

FIG. 5 is a schematic illustrating the use of an ammonothermally grown group-III nitride crystal grown from a vicinal m-plane seed crystal, for generation of m-plane substrates.

FIG. 6 is a schematic illustrating the use of an ammonothermally grown group-III nitride crystal grown from a vicinal m-plane seed crystal, for generation of new seed crystals and/or seed coarsening.

FIG. 7 is a flowchart illustrating the process steps used in one possible embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention discloses a group-III nitride crystal grown using an initially off-oriented non-polar and/or semi-polar growth surface of a group-III nitride seed crystal using the ammonothermal method.

Technical Description

Recent results for optoelectronic and electronic devices make a strong case that some devices, grown on substrates having a non-polar and/or semi-polar surface, may be superior to devices grown on a polar surface. In order to satisfy the need for large non-polar and/or semi-polar substrates, rapid growth along the stable m-plane facet needs to be devised. One method to circumvent the current problem of slow growing m-plane facets, is to start with a seed crystal that has a large m-plane surface area and additionally has been cut with an off-orientation towards an a-plane or c-plane.

One possible scenario to produce these seed crystals would be to grow a large GaN boule along a polar direction using, for example, a well established technique such as hydride vapor phase epitaxy (HVPE). This method allows for rapid growth of good quality GaN along the polar direction. Once a thick GaN boule has been grown, it is possible to cut the boule into wafers with any desirable orientation. Therefore, once properly aligned, it is possible to determine which plane corresponds to the m-plane, and then cut the crystal with any desirable angle with respect to that plane, resulting in an off-oriented m-plane growth surface, or in other words, a highly vicinal m-plane growth surface. This seed can then be used as the seed for ammonothermal growth.

An additional scenario to produce off-oriented seed crystals would be to reuse an existing group-III nitride crystal from a previous ammonothermal growth. The crystal could similarly be cut, polished and/or sliced to expose the desired surface for regrowth. Alternatively, part or all of the crystal may be removed prior to performing a regrowth. The material which is removed may then be used as a source for substrates and/or additional seed crystals.

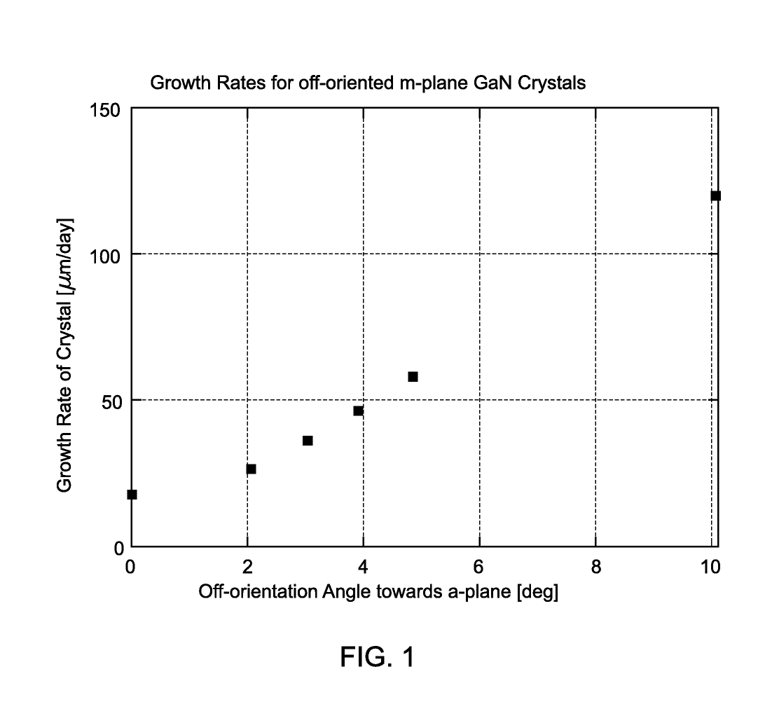

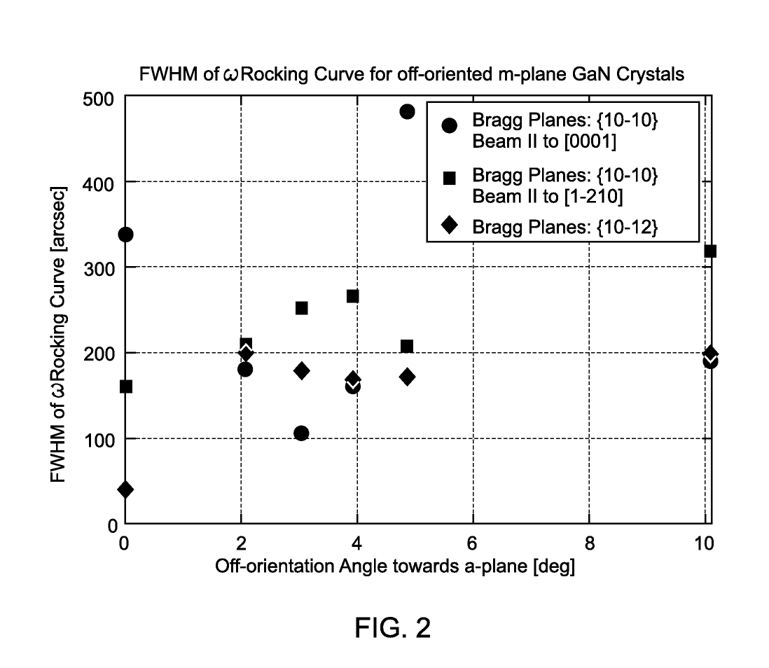

One motivation behind starting with an off-oriented or highly vicinal m-plane growth surface is that the growth rates along the surface normal are enhanced, as can be seen in FIG. 1 (which is a plot of growth rates of m-plane GaN crystals as a function of off-orientation towards the a-plane), while still producing similar crystal quality, as can be seen in FIG. 2 (which is a plot of crystal quality of m-plane GaN crystals as a function of off-orientation towards the a-plane). Specifically, FIG. 2 is a plot of the full width at half maximum (FWHM) for the omega (w) rocking curves from x-ray diffraction (XRD), for both the on-axis {10-10} and off-axis {10-12} Bragg planes. The smaller the FWHM value, the better the crystal quality. Similar numbers represent similar crystal qualities for those particular Bragg planes. These results were generated from an experiment using the ammonothermal method with multiple m-plane seed crystals with varying off-orientation towards the a-direction. The resulting growth rates and crystal quality were measured and recorded and are summarized in FIGS. 1 and 2.

As can be seen from FIG. 1, by miscutting the initial seed crystal from the m-plane direction, the growth rate perpendicular to the surface increases. While a stable m-facet emerges from at least one side of the seed crystal, it may still be favorable to utilize the enhanced growth rates based on geometrical arguments.

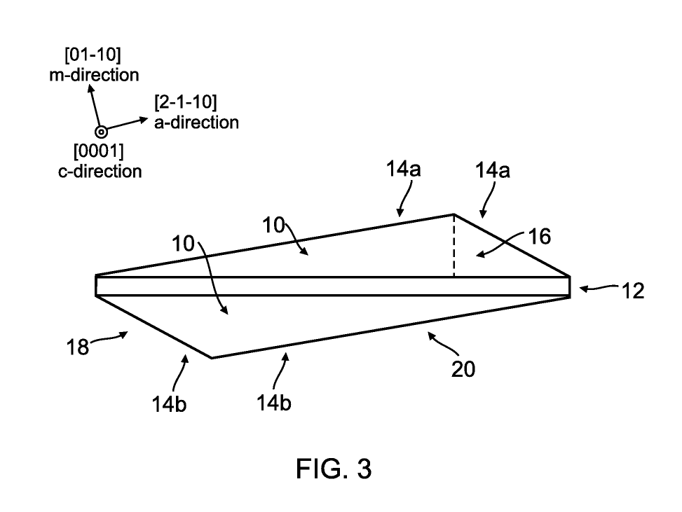

FIG. 3 is a schematic illustration of a final group-III nitride crystal 10 formed after a growth on an m-plane seed crystal with finite off-orientation towards the a-plane, showing the initial off-oriented seed crystal 12 and the stable m-plane surfaces 14a and 14b, as well as the height of the grown layer 16, the shorter equilibrium facet 18, and the longer equilibrium facet 20.

The present invention calculates the height of the resulting crystal 10 by assuming the following:

(1) the initial seed crystal 12 has an m-plane growth surface with an off-orientation towards the a-plane; and

(2) the two resulting stable facets 18 and 20 that emerge are on-axis m-planes 14a and 14b without any significant off-orientation towards the a-plane.

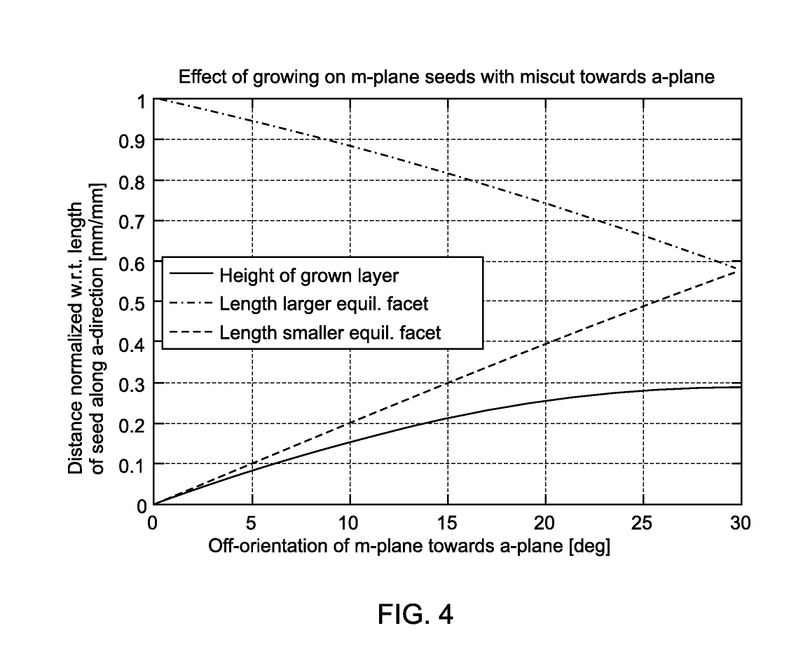

FIG. 4 is a plot of the effect of growing on seed crystals having a growth surface that is an off-oriented m-plane towards the a-plane, that displays the results from the above calculations. The solid line represents the height of the newly grown layer 16, measured from the original surface of the seed crystal 12 to the peak of two m-plane facets 18 and 20 that eventually replace the originally off-oriented surface. The information has been normalized with respect to the length of the seed crystal along the a-direction, meaning, for example, if a seed crystal is used that is 2.5 cm long in the a-direction, and possesses an off-orientation of its m-plane growth surface of 5 degrees towards the a-plane, the increased growth rates along the surface normal will be sustained until a height of approximately 2.5 cm*0.08=2 mm is reached. After this point, only two stable m-plane facets are present, which grow at a slower growth rate.

Additionally, the plot in FIG. 4 provides information on the length of the two stable m-plane facets that will most likely form. For the previous example, the length of the two stable m-plane facets are approximately 2.5 cm*0.95=2.4 cm, and 2.5 cm*0.1=0.25 cm. Note that this model, and any schematics presented in this disclosure, neglect to present or incorporate any growth along the stable m-plane facet which emerges. Growth is assumed to occur on those stable m-planes along with any other facets present, such as polar c-plane facets and/or semi-polar facets, with the end result of additionally expanding the crystal beyond the effects being highlighted in the present invention.

The schematics in FIGS. 3, 5 and 6 aid in portraying some aspects of the present invention. As noted above, FIG. 3 depicts an initially off-oriented m-plane seed crystal with the predicted regrowth. As can be seen, the final habitat of the seed crystal is assumed to be stable m-plane facets, along with any other facets such as semi-polar and/or polar facets.

Applications

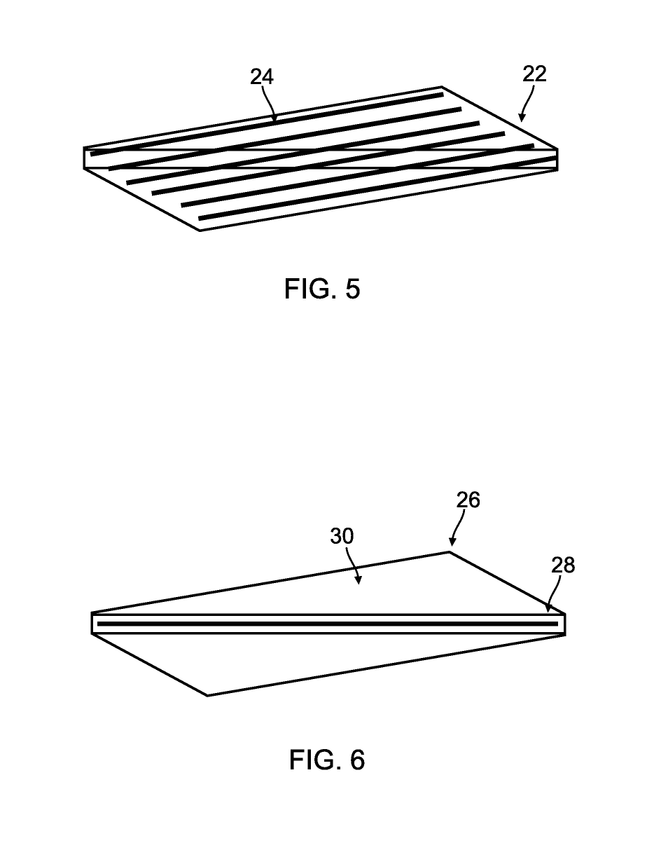

After the growth of the new layers on the seed crystal, various operations can be performed, as desired. One possible scenario would be to slice the entire crystal into on-axis m-plane wafers for future use as substrates. FIG. 5 is a schematic illustration of the use of an ammonothermally grown group-III nitride crystal 22 grown from highly vicinal m-plane seed crystal for the generation of m-plane substrates 24.

Another use of the grown crystal would be to slice the crystal into two or more sections and use those sections to perform a regrowth with the enhanced growth rates due to the off-orientation of the seed crystal surface. FIG. 6 is a schematic illustration of the use of ammonothermally grown group-III nitride crystal 26 grown from highly vicinal m-plane seed crystal for generation of new seed crystals and/or seed coarsening, wherein the seed is cut along line 28 to create two large seeds 30a and 30b from one smaller seed.

Additionally, any combination of the two above operations may be formed and/or in addition to other operations not explicitly mentioned in this invention.

Bulk GaN seed crystals, large size GaN substrates for development of optoelectronic/electronic devices, e.g., Light Emitting Diodes (LEDs), Light Amplification by Stimulated Emission of Radiation (LASERs), High Electron Mobility Transistors (HEMTs), etc., may be fabricated using the method of the present invention. Growth parameters/crystal orientation may be refined to improve overall results.

Advantages and Improvements

Overall, the present invention enables rapid growth of non-polar substrates, and decreases growth time required as compared to existing known conditions for growth. The present invention also enables rapid seed crystal coarsening and/or multiplication for storage/future use.

Process Steps

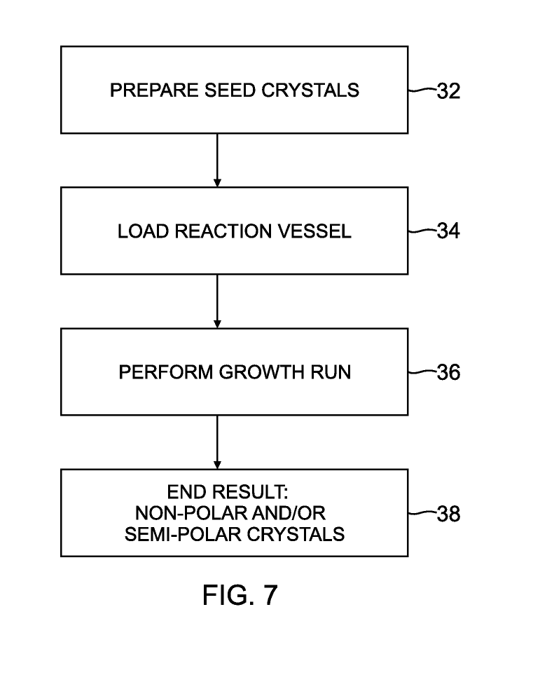

FIG. 7 is a flowchart illustrating the process steps used in one embodiment of the present invention.

Block 32 represents preparing the seed crystals for ammonothermal growth, wherein the seed crystals have one or more non-polar or semi-polar growth surfaces. Specifically, this block varies the surface orientation of the starting m-plane (10-10) GaN seed crystals in order to affect the growth rates and crystal quality of the ammonothermally grown GaN crystals. Moreover, the seed crystals may be coarsened along non-polar or semi-polar directions prior to the ammonothermal growth.

The non-polar or semi-polar growth surfaces of the seed crystals are initially off-oriented growth surfaces, wherein the initially off-oriented growth surfaces are off-oriented m-plane growth surfaces. The off-oriented m-plane growth surfaces may be created by cutting group-III nitride crystals at a desired angle with respect to an m-plane of the group-III nitride crystal, wherein the off-oriented m-plane growth surfaces have an off-orientation in an a-plane direction or a c-plane direction. In one embodiment, the off-orientation in the a-plane direction may range from approximately 0° to approximately 15°. In another embodiment, the off-orientation in the c-plane direction may range from approximately 0° to approximately 45°. However, other growth surface off-orientations may be used as well.

Experimentally, this was done by preparing six Mitsubishi Chemical Corporation's freestanding, HVPE grown, atomically flat, m-plane GaN seed crystals with nominal growth surface off-orientations towards the a-plane ranging from approximately 0° to approximately 10°, namely: 0°, 2°, 3°, 4°, 5°, and 10°.

Block 34 represents the loading of the reaction vessel, wherein one or more of the seed crystals are placed into a higher temperature zone of a 25 mm diameter “René 41” autoclave, along with polycrystalline GaN source materials held in a Ni—Cr mesh basket, which is placed in a lower temperature zone of the autoclave. In addition, baffles are placed in between the two temperature zones of the autoclave along with sodium metal.

Block 36 represents ammonothermally growing the group-III nitride crystals by performing one or more growth runs of the reaction vessel, wherein the autoclave is filled with a nitrogen-containing solvent for dissolving the source materials, such as ammonia, and heated to 500-600° C. to produce pressures of 150-250 MPa, thereby transporting a fluid comprised of the solvent with the dissolved source materials to the seed crystals for growth of the group-III nitride crystals on the seed crystals. The growth run is performed for some specified time period, after which the autoclave is cooled, the ammonia released, and the crystals removed.

Block 38 represents the end result of the process steps, namely high-quality, large non-polar and/or semi-polar GaN crystals needed to produce substrates for improved optoelectronic and electronic group-III nitride devices. Note that the ammonothermally grown group-III nitride crystals themselves may be used as seed crystals.

Experimentally, the total thickness of the newly grown crystals from Block 38 ranged from approximately 88 μm to approximately 644 μm for growth runs extending to 6 days.

As noted above, FIGS. 1 and 2 illustrate the results for growth runs performed experimentally. From FIG. 1, it can be seen that the growth rate linearly increases with increasing initial off-orientation of the m-plane growth surfaces of the seed crystals towards the a-plane. From the FWHM of the w rocking curve for the crystals in FIG. 2, it can be seen that, despite increasing the growth rate by up to a factor of 7, the quality remains similar as seen by the on-axis {10-10} and off-axis {10-12} FWHM values. Determination of the surface off-orientation using x-ray diffraction methods after growth on the seeds revealed that the prevalent facet was still parallel to the initial seed crystal surface, whereas a smaller, stable m-plane facet started to emerge from one of the a-plane edges of the seed. This result indicates that the steps introduced by the miscut grew out to a stable facet, while allowing for an overall increased growth rate in a non-polar direction with similar crystal quality. This result demonstrates a potential application for seed crystal coarsening and generation of non-polar substrates.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing group-III nitride crystals, comprising:
(a) placing group-III-containing source materials and group-III nitride seed crystals into a vessel, wherein the seed crystals have one or more non-polar or semi-polar growth surfaces; and
(b) ammonothermally growing the group-III nitride crystals by filling the vessel with a nitrogen-containing solvent for dissolving the source materials and transporting a fluid comprised of the solvent with the dissolved source materials to the seed crystals for growth of the group-III nitride crystals on the seed crystals.

2. The method of claim 1, wherein the non-polar or semi-polar growth surfaces are initially off-oriented growth surfaces.

3. The method of claim 2, wherein the initially off-oriented growth surfaces are off-oriented m-plane growth surfaces.

4. The method of claim 3, further comprising creating the off-oriented m-plane growth surfaces by cutting group-III nitride crystals at a desired angle with respect to a m-plane of the group-III nitride crystal.

5. The method of claim 3, wherein the off-oriented m-plane growth surfaces have an off-orientation in an a-plane or c-plane direction.

6. The method of claim 5, wherein the off-orientation in the a-plane direction ranges from approximately 0° to approximately 15°.

7. The method of claim 5, wherein the off-orientation in the c-plane direction ranges from approximately 0° to approximately 45°.

8. The method of claim 1, further comprising coarsening the seed crystals along non-polar or semi-polar directions prior to the ammonothermal growth.

9. The method of claim 1, wherein the ammonothermally grown group-III nitride crystals are used as the seed crystals.

10. A group-III nitride crystal grown by the method of claim 1.

11. An apparatus for growing group-III nitride crystals, comprising:
(a) a vessel;
(b) wherein group-III-containing source materials and group-III nitride seed crystals are placed into the vessel, and the seed crystals have one or more non-polar or semi-polar growth surfaces; and
(c) wherein the group-III nitride crystals are ammonothermally grown by filling the vessel with a nitrogen-containing solvent for dissolving the source materials and transporting a fluid comprised of the solvent with the dissolved source materials to the seed crystals for growth of the group-III nitride crystals on the seed crystals.

12. The apparatus of claim 11, wherein the non-polar or semi-polar growth surfaces are initially off-oriented growth surfaces.

13. The apparatus of claim 12, wherein the initially off-oriented growth surfaces are off-oriented m-plane growth surfaces.

14. The apparatus of claim 13, wherein the off-oriented m-plane growth surfaces is created by cutting group-III nitride crystals at a desired angle with respect to a m-plane of the group-III nitride crystal.

15. The apparatus of claim 13, wherein the off-oriented m-plane growth surfaces have an off-orientation in an a-plane or c-plane direction.

16. The apparatus of claim 15, wherein the off-orientation in the a-plane direction ranges from approximately 0° to approximately 15°.

17. The apparatus of claim 15, wherein the off-orientation in the c-plane direction ranges from approximately 0° to approximately 45°.

18. The apparatus of claim 11, wherein the seed crystals are coarsened along non-polar or semi-polar directions prior to ammonothermal growth.

19. The apparatus of claim 11, wherein the ammonothermally grown group-III nitride crystals are used as the seed crystals.

20. A composition comprising a group-III nitride seed crystal for use in ammonothermal growth, wherein the seed crystal has one or more non-polar or semi-polar growth surfaces, and the growth surface is an initially off-oriented growth surface comprising an off-oriented m-plane growth surface with an off-orientation in an a-plane or c-plane direction.

21. The composition of claim 20, wherein the non-polar or semi-polar growth surfaces are initially off-oriented growth surfaces.

22. The composition of claim 21, wherein the initially off-oriented growth surfaces are off-oriented m-plane growth surfaces.

23. The composition of claim 22, wherein the off-oriented m-plane growth surfaces are created by cutting group-III nitride crystals at a desired angle with respect to a m-plane of the group-III nitride crystal.

24. The composition of claim 22, wherein the off-oriented m-plane growth surfaces have an off-orientation in an a-plane or c-plane direction.

25. The composition of claim 24, wherein the off-orientation in the a-plane direction ranges from approximately 0° to approximately 15°.

26. The composition of claim 24, wherein the off-orientation in the c-plane direction ranges from approximately 0° to approximately 45°.

27. The composition of claim 20, wherein the seed crystals are coarsened along non-polar or semi-polar directions prior to the ammonothermal growth.
